(19) United States
(12) Patent Application Publication
(10) Pub. No.: US 2010/0252918 A1
(43) Pub. Date: Oct. 7, 2010

(54) MULTI-DIE PACKAGE WITH IMPROVED HEAT DISSIPATION

(76) Inventors: Hunt H. Jiang, San Jose, CA (US); Eric Yang, Saratoga, CA (US); Michael R. Hsing, Saratoga, CA (US); Frank Ren, Hangzhou (CN)

Correspondence Address: PERKINS COIE LLP;PATENT-SEA, P.O. BOX 1247, SEATTLE, WA, 98111-1247, US

(21) Appl. No.: 12/419,212

(22) Filed: Apr. 6, 2009

(51) Int. Cl. H01L 23/34; H01L 23/52; H01L 23/28; H01L 21/98

(52) U.S. Cl. 257/675; 438/107; 257/E23.141; 257/E23.08; 257/E23.116; 257/E21.705

(57) ABSTRACT

The present invention discloses a multi-die package which facilitates heat dissipation for a high power consumption die. In the package, part of the lead frame is bent so as to be exposed at the surface of the package. On the opposite side of the exposed surface, a high power consumption die is attached. The other die with lower power consumption is not at the surface of the multi-die package.

### TECHNICAL FIELD

The present invention relates to integrated circuit packaging, and more particularly, to a multi-die packaging with heat dissipation function.

### BACKGROUND

The flyback converter in off-line applications favors a single package that contains both the switch device die and the controller die wherein the controller die consumes a moderate amount of energy and the switch device die consumes a relatively high amount of energy. The switch device die generally generates significant heat. Thus, heat dissipation is essential and affects the reliability of the die.

Conventional applications often apply a SOP (small outline package) type package as seen in FIG. 1. In the package 10, a power die 11 and a normal die 12 are attached on a lead frame 16. The dies communicate with each other and with the outside by the use of bonding pads 17. The bonding pads 17 can be used to connect one die to the other die and the dies to the lead frame 16 with wire bonds 15. The structure is encapsulated by a mold compound 13 while parts of the leads 14 are exposed to form the pins 141. In this package 10, the heat dissipates mainly through the mold compound 13 to the outside or through conventional fused pins. The heat dissipation through mold compound 13 is not particularly effective for heat dissipation since the thermal conductivity of the mold compound is worse than the metal. Further, the cross-sectional area of the fused pin is small which has limited heat dissipation capability. In these approaches, the heat cannot be dissipated sufficiently well and the power die 11 will have a high junction temperature which affects the reliability. The high temperature of the pins 141 may also affect the cohesion between the pins 141 and the PCB board. Thus, a new package with higher heat dissipation ability is desired for power supply applications.

### BRIEF DESCRIPTION OF THE DRAWINGS

The accompanying drawings, which are incorporated in and form a part of this specification, illustrate embodiments of the invention and, together with the description, serve to explain the principles of the invention.

FIG. 1 shows a prior art SOP type package;

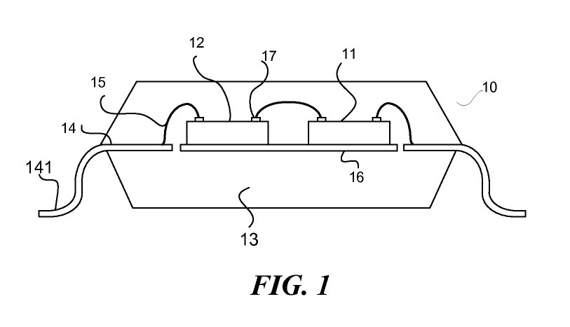

FIG. 2 shows a sectional view of a heat dissipation package in accordance with a first embodiment of the present invention;

FIG. 3 shows an isometric view of the heat dissipation package of FIG. 2;

FIG. 4 shows a top plan view of the dies mounted on the lead frame before the compound molding step;

FIG. 5 shows a heat dissipation package used with a heat sink in accordance with a second embodiment of the present invention;

FIG. 6 features another heat dissipation package dissipating heat through PCB board in accordance with the a embodiment of the present invention;

FIG. 7 shows a different depth of the normal die in accordance with the present invention;

FIG. 8 illustrates the lead frame structure of the present invention which is bent to pull the die attach paddle to the surface of the package;

FIG. 9 illustrates the packaging process of the heat dissipation package in accordance with the present invention; and

FIG. 10 shows an illustrative process of press molding for the lead frame.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

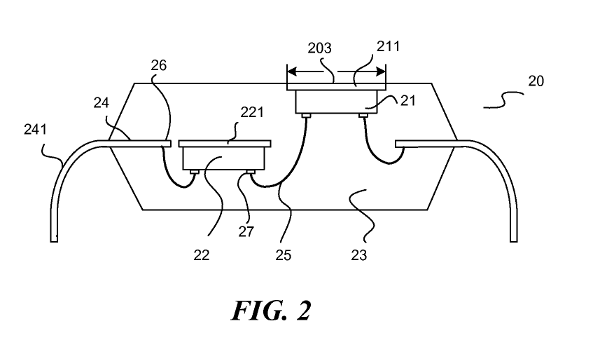

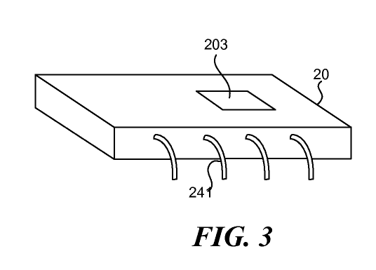

FIG. 2 illustrates a cross-sectional view of a heat dissipation package 20 in accordance with a first embodiment of the present invention. An isometric view is shown in FIG. 3. The package 20 comprises a lead frame 26 with pins 241 outside of the package 20, at least one normal die 22, and at least one power die 21 which consumes higher power compared to the normal die 22. For example, the normal die 22 may implement control functions that control the operation of the power die 21, which may contain power switching devices.

A power die attach paddle 211 of the lead frame 26 has one surface mounted onto the power die 21. An opposite surface of the paddle 211 is exposed at the surface of the package 20. As seen, the power die 21 is raised up to near the surface of the package 20 while the normal die 22 remains at the center of the package 20. In the present invention, the power die refers to the die consuming relative high power, and the normal die refers to the die consuming relative less power compared to the power die. In one embodiment, the normal die is a controller for the power converter or contains a controller. The power die contains one or more FET switch devices. The power die 21 is attached on the power die attach paddle 211 of the lead frame 26. The power die attach paddle 211 has its back side exposed outside of the package 20 which is the opposite side to the surface that mounted the power die 21. The exposed surface 203 or the back side of the power die attach paddle 211 can also be seen in FIG. 3.

The lead frame 26 is comprised of, in one example, a metal with good thermal conductivity. For example, copper may be a typical metal employed. In the present invention, the dies are at different depths inside the package 20 with the power die 21 mounted near the surface, exposing the back side of the power die attach paddle 211 at the surface of the package 20. Thus, the lead frame 26 has the portion of the power die attach paddle 211 being at a different depth from the other part the lead frame 26. The power die attach paddle 211 is at a different depth than the other part of the lead frame 26, when the lead frame is viewed in cross section. Where the power die 21 is a voltage converter, the power die 21 can dissipate heat easily through the power die attach paddle 211 with good thermal conductivity while the controller together with the normal die attach paddle 221 are encapsulated inside the package 20. This ensures good mechanical and electrical reliability for the controller (normal die 22). Further, some of the pads 27 on the dies are connected to the lead frame 26 by wire bonds 25 to communicate signal between the dies and outside circuits, and some of the pads 27 on power die 21 are also connected accordingly to the pads 27 on the normal die 22 by wire bonds 25 to achieve communication between the dies inside the package.

In one embodiment, the interconnection between the dies inside the package can also be achieved by connecting the pads 27 on the power die 21 and the normal die 22 to the lead frame 26 first and then bonding the desired leads 24 together with wire bonds 25. The power die 21, the normal die 22, the lead frame 26 together with the wire bonds 25 are encapsulated by mold compound 23, leaving the exposed surface 203 of the power die attach paddle 211 and the pins 241 outside of the mold compound and forms the package 20. In one embodiment, the number of power die 21 can be one or more in the same or different power die attach paddle. In another embodiment, the number of normal die 22 can be one or more in the same or different normal die attach paddle 221.

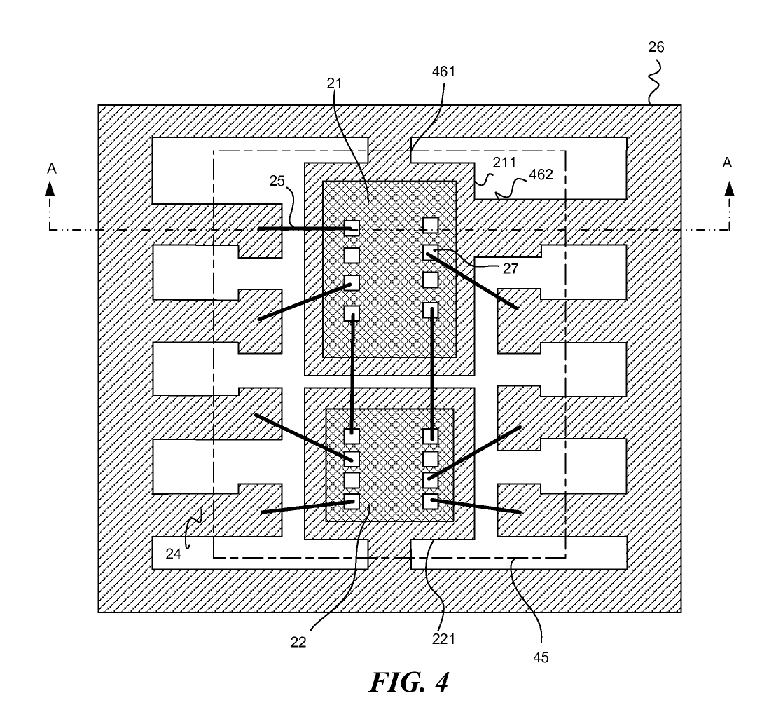

FIG. 4 shows a top plan view of the dies mounted on the lead frame 26 before the encapsulation step. The lead frame 26 is indicated by the diagonal cross-hatching. The lead frame 26 comprises the power die attach paddle 211, normal die attach paddle 221, leads 24 and supporting structure of tie bar 461. The supporting structure can further include the fused leads 462 to support the lead frame 26 during the packaging process. The power die 21 is mounted at the power die attach paddle 211 and the pads 27 are made on the power die 21. The normal die 22 is mounted at the normal die attach paddle 221 and the pads 27 are made on the normal die 22. Some of the pads 27 are connected to the leads 24 by wire bonds 25 to communicate between the dies and the outside circuit. Some other pads 27 are connected by wire bonds 25 to communicate between the power die 21 and the normal die 22. In the present invention, the power die attach paddle 211 of the lead frame 26 is at a different depth from the other parts of the lead frame 26. The power die attach paddle 211 is at a lower level in this view. The rectangular dashed region 45 represents the boundary of the mold compound 23 with thickness to encapsulate the normal die attach paddle 221, dies and wire bonds 25, leaving the power die attach paddle 211 exposed at the surface of the mold compound and to form the package.

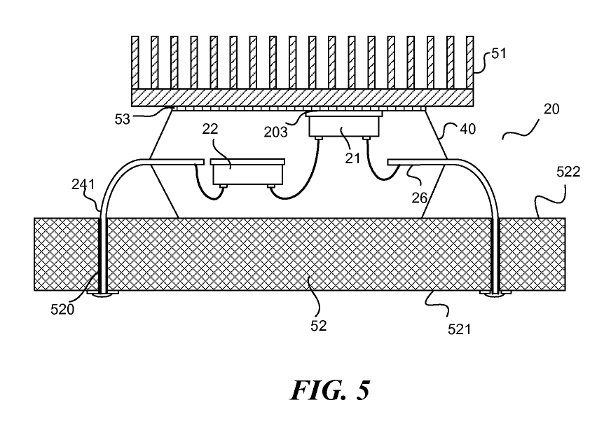

FIG. 5 shows a heat dissipation package 20 application in accordance with a second embodiment of the present invention. In this embodiment, the exposed surface 203 of the lead frame 26 contacts with a heat sink 51 to improve heat dissipation. Thus, the pins 241 extend in the opposite direction of the exposed surface 203. In one embodiment, the pins 241 of the heat dissipation package us the through-hole package format. As seen, this application system comprises the heat dissipation package 20, a heat sink 51 and a PCB board 52. The PCB board 52 contacts the package 20 at its top surface 522 of the PCB board 52, has holes 520 to hold the pins 241 of the package 20 and connects the pins 241 at the other side 521 of the PCB board 52. For this embodiment, the heat dissipation package 20 has its pins 241 extending downwards as shown, the opposite direction of the exposed surface 203 so as to facilitate the mounting of the heat sink 51. Between the exposed surface 203 of the package 20 and the heat sink 51, a thermal film layer 53 can be added to ensure thorough contact and facilitates the heat dissipation. In another embodiment, the package can adopt a surface-mounted format with the pins extending the opposite direction of the exposed surface 203, and the PCB board has circuit printed on the top surface 522. In yet another embodiment, the package can be a ball grid array package with balls planted on the opposite surface of the exposed surface 203.

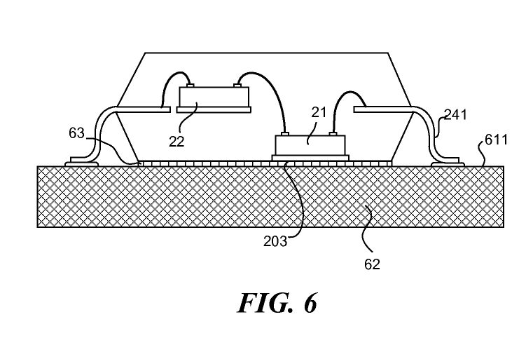

FIG. 6 features another heat dissipation package application in accordance with a third embodiment of the present invention in which the exposed surface 203 contacts with the thermal conductive layer of the PCB board. In this embodiment, the power die 21 dissipates heat through the exposed surface 203 and the metal layer on the PCB board 62. Thus, in this application, pins 241 grow in the same direction with the exposed surface 203. One embodiment in FIG. 6 employs the format of surface-mounted package such as SOP type. As seen, the pins 241 extend in the same direction as the exposed surface 203 for the power die 21 to facilitate the surface mounting of the package wherein the exposed surface 203 contacts the PCB board 62 which has good thermal conductive layer at its surface 611. The circuit can be printed on either side or both side of the PCB board 62. In another embodiment, the package also can use the through-hole format with pins held by the holes of PCB board and extend in the same direction of the exposed surface 203. Meanwhile, the pins 241 are connected to the PCB board at the bottom side. Between the package 20 and the PCB board, a thermal film layer 63 can be added to achieve good contact and promotes heat dissipation.

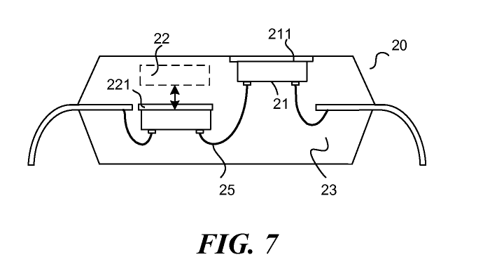

FIG. 7 shows that the depth of the normal die 22 in the package 20 can be in any level while keep the power die attach paddle 211 exposed at the surface of the package 20. The depth of the normal die 22 can be either in the center level of the package 20, or be moved upper-wards or down-wards. However, in some applications the normal die attach paddle 221 is not exposed at the surface of the package 20 to prevent electrical signal interference from the power die 21 through the possible conductive path of the heat sink or the PCB board.

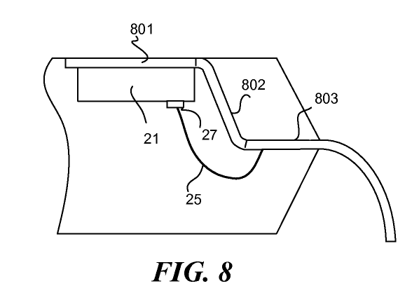

FIG. 8 illustrates the structure of the lead frame of the present invention wherein at least one of the die attach paddle is placed at a different depth. This sectional figure only shows a part of the lead frame which is at the position of line A in FIG. 4. The lead frame includes 3 parts. They are the exposed part 801, the inclined part 802 and the base part 803. The exposed part 801 is mainly the power die attach paddle. The inclined part 802 connects the exposed part 801 and the base part 803 with an angle from them while the exposed part plane and the base part plane are in parallel. The wire bonds 25 connect the pads 27 on the power die 21 and the bottom surface of the base part 803 as shown. In one embodiment, the exposed part 801of the lead frame may contain two or more power die attach paddles with each mounted a power die. In yet another embodiment, there can be two or more power dies attached on one power die attach paddle.

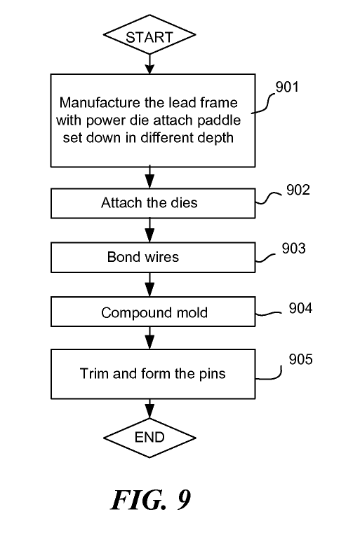

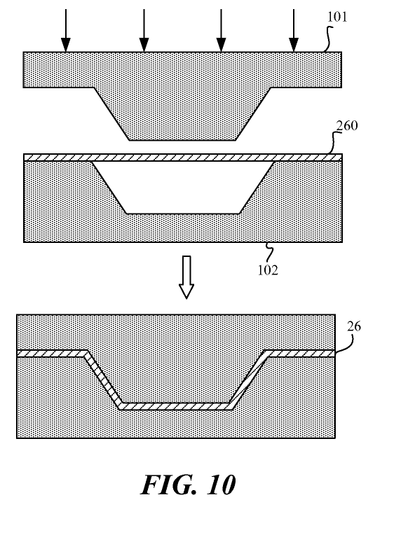

FIG. 9 illustrates the packaging process of the heat dissipation package in accordance with the present invention. In box 901, a lead frame is manufactured with the power die attach paddle set at a different depth than the normal die attach paddle. The lead frame comprises the die attach paddles, leads, and one or more tie bar. Fused leads can be further comprised in the lead frame. The power die attach paddle is a paddle used to mount the power die with relative higher power compared to the other dies in the same package. The power die attach paddle can be set down in different depth from the other part of the lead frame by a simple press molding from a pattern. The illustrative press molding process for the lead frame is shown in FIG. 10. First, the plane pattern of the lead frame 260 is under a matched concavo-convex upper mold 101 and down mold 102. The pattern of the mold 101 and 102 is the same with the power die attach paddle or power die attach paddles required to be exposed at the surface of the package. After application of a force onto the upper mold 101, the power die attach paddle of the lead frame 26 is set down at a different depth from the other part of the lead frame 26. The power die attach paddle is set down at a deeper depth in the view of facing the die attaching surface. The offset of the power die attach paddle ensures an exposed surface of the lead frame and heightens the heat dissipation ability. The bend of the power die attach paddle can be formed with other methods than press molding. The distance of the power die attach paddle plane from the original lead frame plane is decided by the mechanical strength requirement, mold compound encapsulation technique or others.

In box 902, the dies are attached on the die attach paddles of the lead frame. The power die is attached on the power die attach paddle and the normal die is attached on the normal die attach paddle. In box 903, the bond wires are attached. The pads on the power die are bonded to the leads of the lead frame and some pads on the normal die with wire bonds. Some other pads on the normal die are bonded to the leads of the lead frame with wire bonds. The wires can be gold wires, aluminum wires or the other conductive material. The wire bonding allows electrical communication between the two dies and the electrical communication between the dies and the outside circuits.

In box 904, the lead frame, dies, and wire bonds are encapsulated with a mold compound. The encapsulation depth ensures the power die attach paddle exposed at the surface of the mold compound, and also leaves the pins out of the mold compound. In box 905, the pins are formed and trimmed and the entire package is complete.

In some other embodiments, there can be more than one die attach paddle exposed with the back side on the surface of the package. In another embodiment, there can be more than one die on a die attach paddle.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

I/We claim:

1. An integrated circuit package comprising:
a lead frame having pins, a power die attach paddle, and a normal die attach paddle;
molding material
at least one normal die;
at least one power die consuming a larger amount of power compared to said normal die, wherein said at least one power die is mounted to the power die attach paddle, further wherein said power die attach paddle is exposed at the surface of said molding material.

2. The package in claim 1, wherein said lead frame further comprises:
an exposed part comprised of said power die attach paddle;
a base part parallel to said exposed part and on which bonding wires lead from said exposed part to pads on said power die; and
an inclined part, connecting said exposed part and said base part at an angle.

3. The package in claim 2 wherein said lead frame is made from copper.

4. The package in claim 1, wherein said power die contains a FET switch device.

5. The package in claim 1, wherein said normal die contains controller circuitry for said power die.

6. The package in claim 1, wherein said normal die is at the center level of said molding material.

7. The package in claim 1, wherein said normal die is located not at the surface of said molding material.

8. The package in claim 1, wherein:
select pads on said power die are connected to select pads on said normal die by wire bonds; and
select pads on said power die and said normal die are connected to said lead frame by wire bonds.

9. The package in claim 1, wherein the pads on said normal die and the pads on said power die are connected to said lead frame by wire bonds such that some of said wire bonds are wholly encapsulated by said molding material.

10. The package in claim 8, wherein said power die, said normal die, said wire bonds and said lead frame are encapsulated by the molding material, leaving the exposed surface of said power die attach paddle and said pins outside of said molding material.

11. The package in claim 1, wherein said pins extend the opposite direction from said exposed surface.

12. The package in claim 11, wherein said exposed surface contacts with a heat sink.

13. The package in claim 12, wherein a thermal film is added between said exposed surface and said heat sink.

14. The package in claim 12, wherein said package is adapted for use with a through-hole package, SOP package or ball grid array package.

15. The package in claim 1, wherein said pins extend the same direction with said exposed surface and said exposed surface contacts with a PCB board with thermal conductive layer.

16. The package in claim 15, wherein said package is adapted for use with a through-hole package or SOP package.

17. The package in claim 15, wherein a thermal film is added between said exposed surface and said PCB board.

18. The package in claim 1 wherein the lead frame includes at least two power die attach paddles with each mounted thereon a power die.

19. A packaging process for multi-die heat dissipation comprising:
manufacturing the lead frame with a power die attach paddle formed at a different depth from a normal die attach paddle;
attaching a power die onto said power die attach paddle;
attaching a normal die onto said normal die attach paddle;
using bonding wires to electrically connect said power die, normal die, and said lead frame;
encapsulating said lead frame, dies and wire bonds with a molding material; and
trimming and forming pins.

20. The packaging process in claim 19, wherein said power die attach paddle is set down by press molding.
